(19) United States
(12) Patent Application Publication
(10) Pub. No.: US 2008/0220596 A1
(43) Pub. Date: Sep. 11, 2008

(54) Delivery of Low Pressure Dopant Gas to a High Voltage Ion Source

(75) Inventors: W. Karl Olander, Indian Shores, FL (US); Jose I. Arno, Brookfield, CT (US); Robert Kaim, Brookline, MA (US)

Correspondence Address: INTELLECTUAL PROPERTY / TECHNOLOGY LAW, PO BOX 14329, RESEARCH TRIANGLE PARK, NC, 27709, US

(73) Assignees: ADVANCED TECHNOLOGY MATERIALS, INC., Danbury, CT (US); ADVANCED TECHNOLOGY MATERIALS, INC., Danbury, CT (US)

(21) Appl. No.: 12/065,471

(22) PCT Filed: Aug. 29, 2006
(86) PCT No.: PCT/US06/34135

§ 371 Date: Apr. 14, 2008

Related U.S. Application Data
(60) Provisional application No. 60/712,648, filed on Aug. 30, 2005.

(51) Int. Cl. H01L 21/265; H01J 37/317; H01J 37/08

(52) U.S. Cl. 438/514; 250/424; 250/427; 250/492.21; 257/E21.334

(57) ABSTRACT

A system for delivery of low-pressure dopant gas to a high-voltage ion source in the doping of semiconductor substrates, in which undesired ionization of the gas is suppressed prior to entry into the high-voltage ion source, by modulating electron energy upstream of the high-voltage ion source so that electron acceleration effects are reduced to below a level supporting an electronic ionization cascade. The gas delivery system in a specific application includes a gas flow passage, a voltage generator electrically coupled with at least a portion of the gas flow passage to impose an electric field thereon, and an obstructive structure that is deployed to modulate acceleration length of electrons of the low-pressure gas in relation to ionization potential of the gas, to suppress ionization in the gas flow passage.

### BACKGROUND OF THE INVENTION

1. Field of the Invention

The present invention relates to delivery of low-pressure dopant gas to a high voltage ion source in the doping of materials such as semiconductor substrates.

2. Description of the Related Art

U.S. Pat. No. 5,518,528 issued May 21, 1996 to Glenn M. Tom, et al. describes an adsorbent-based fluid storage and delivery system useful in the supply of gas for semiconductor manufacturing operations, e.g., ion implantation. In such system, fluid is sorptively retained on a physical adsorbent medium of suitable adsorptive affinity in a fluid storage and dispensing vessel, and the fluid is desorbed from the physical adsorbent medium under dispensing conditions. The fluid storage and dispensing vessel can for example be a metal cylinder, and the dispensing conditions can involve a thermally-assisted desorption of the fluid from the adsorbent medium, pressure-differential-based desorption of the fluid from the adsorbent medium, and/or concentration gradient-based desorption of the fluid from the adsorbent medium, such as by passage of a carrier gas through the vessel for contact with the adsorbent medium having fluid adsorbed thereon.

The adsorbent-based fluid storage and dispensing system of U.S. Pat. No. 5,518,528 has been commercialized by ATMI, Inc. (Danbury, Conn.) under the trademark SDS, and has been widely used in ion implantation applications, for supply of dopant gas to the ion source unit, for generation of ions that are passed to the implanter.

The ion implantation system includes a supply of the dopant gas (e.g., arsine, phosphine, germane, silane, etc.), which may be constituted by a conventional high-pressure gas cylinder containing such dopant gas, or alternatively a low-pressure adsorbent-based doping gas supply such as the SDS® dopant gas supply, and a gas box, an ion source unit, an implanter, and associated flow circuitry and instrumentation. In the ion implantation system, the dopant gas supply vessels are always located in the gas box of the system. The gas box is an enclosure connected to and at the same high voltage as the ion source unit.

The foregoing ion implantation system, while generally effective, suffers the deficiency that it has not been possible to deliver toxic, corrosive or flammable dopants to the ion source unit from dopant gas supply vessels at ground potential. There are two primary reasons for such deficiency:
(1) The gas delivery line from the dopant gas supply vessel would have to be made of insulating material, and for high pressure dopant supplies there is no acceptable way to deliver the high-pressure gas due to safety issues related to the reliability of insulating lines and connections to such lines, as required to accommodate high pressure dopant gas delivery operation.
(2) For low-pressure (e.g., sub-atmospheric pressure) dopant gas supplies, such as the aforementioned SDS® dopant gas supply, there is a risk of arcing and plasma discharges in the gas line as a consequence of the ionization of the low-pressure gas, due to the high voltage gradient that is necessarily applied across the insulated gas delivery line in the use of low-pressure gases.

Rzeszut, et al. U.S. Pat. No. 6,515,290 issued Feb. 4, 2003 describes a gas delivery system for an ion implantation system that includes a gas supply at a first voltage potential and an ion source at a second voltage potential, in which the second voltage potential is larger than the first voltage potential, and an electrically insulative connector is coupled between the gas supply and the ion source. In operation, the supply gas is delivered from the storage location at the first voltage potential to the ion source of the ion implantation system at the second voltage potential.

The system disclosed by Rzeszut, et al. utilizes a high voltage isolator for transporting dopant gases across the high voltage. The isolator apparatus includes two linear concentric tubes made of insulating material, in which the dopant gas is flowed through the inner tube and an inert gas is flowed through the annular space between the inner and outer tubes. In this arrangement, the inert gas is at higher pressure than the dopant gas, so that if a leak occurs inert gas will flow inwardly rather than dopant gas escaping. However, this apparatus has the disadvantage that, in order to prevent ionization breakdown of the dopant gas, either the high voltage isolator has to be very long, or the pressure of the dopant gas has to be very high.

As an example, if the dopant gas has an electron mean free path of 0.5 mm at a pressure of 1 torr, and an ionization potential of 10 eV, then a tube about 10 meters in length would be required to prevent breakdown across a 200 kV voltage gap with a dopant gas pressure of 1 torr. This length is impractical for a straight (linear) tube. In order to reduce the length of the tube, the minimum dopant pressure would have to be greatly increased, which would correspondingly reduce the amount of gas available from the low pressure dopant gas supply (the aforementioned SDS® dopant gas supply, for example, delivers a large proportion of its contents at pressures between 5 and 100 torr). The alternative of using a high-pressure gas supply would create an unacceptable risk of a potentially catastrophic release of the hazardous dopant gas in the event of leakage of high-pressure gas from the supply vessel, the high-voltage isolator, or associated flow circuitry (pumps, valves, fittings, etc.).

It would therefore be a significant advance in the art to utilize a low-pressure dopant gas supply, due to the increased safety characteristic of such sources in relation to high-pressure supplies, but without the high susceptibility to arcing and plasma discharge in the presence of high voltage gradients, as characteristic of prior art systems.

The provision of such an improved low-pressure dopant gas supply arrangement permitting dopant gases to be delivered at ground potential would (i) enable the low-pressure gas supply vessel to be removed from the gas box, thereby freeing up valuable space inside the high-voltage terminal of the implanter, (ii) render dopant gas delivery to the implanter simpler and more efficient in character, and (iii) enable the use of large dopant gas vessels, which would in turn increase the operating time (uptime) of the system between successive vessel change-outs, as well as making such vessel change-outs simpler and speedier.

### SUMMARY OF THE INVENTION

The present invention relates to delivery of low-pressure dopant gas to a high voltage ion source in the doping of materials such as semiconductor substrates.

The invention relates in one aspect to a gas delivery apparatus adapted to transfer low-pressure gas from a supply thereof to an ion source characterized by an elevated voltage potential in relation to such supply, the gas delivery apparatus including a gas flow passage, a voltage generator electrically coupled with at least a portion of the gas flow passage to impose an electric field thereon, and an obstructive structure adapted to modulate acceleration length of electrons of the low-pressure gas in relation to ionization potential of the low-pressure gas in the gas flow passage, to suppress ionization of the low-pressure gas in said gas flow passage.

In another aspect, the invention relates to a semiconductor manufacturing facility, including a gas delivery apparatus of the aforementioned type.

Yet another aspect of the invention relates to a semiconductor manufacturing facility, including an ion implantation system including a low-pressure gas supply, an ion source adapted to receive low-pressure gas from the low-pressure gas supply and produce ion implant species, an implant chamber adapted to receive the ion implant species and impinge same on a semiconductor device substrate to produce an implanted substrate article, and a gas delivery apparatus adapted to transfer the low-pressure gas from the supply thereof to said ion source, the gas delivery apparatus comprising a gas flow passage, a voltage generator electrically coupled with at least a portion of the gas flow passage to impose an electric field thereon, and an obstructive structure adapted to modulate acceleration length of electrons of the low-pressure gas in relation to ionization potential of the low-pressure gas in the gas flow passage, to suppress ionization of the low-pressure gas in the gas flow passage.

A further aspect of the invention relates to a method of delivering low-pressure gas from a supply thereof to an ion source characterized by an elevated voltage potential in relation to the supply, such method including providing a gas flow passage, imposing an electric field on at least a portion of the gas flow passage, and modulating acceleration length of electrons of the low-pressure gas in relation to ionization potential of the low-pressure gas in the gas flow passage, to suppress ionization of the low-pressure gas in the gas flow passage.

In another aspect, the invention relates to a method of manufacturing a semiconductor product, including using a gas delivery apparatus of the aforementioned type to deliver a gas for such manufacturing.

A still further aspect of the invention relates to a method of manufacturing a semiconductor product, including ion implantation using a low-pressure gas, ionizing the low-pressure gas to produce ion implant species, and impinging the ion implant species on a semiconductor device substrate to produce an implanted substrate article, in which the method includes flowing the low-pressure gas through a gas flow path to an ion source for such ionizing, imposing an electrical field on a least a portion of the gas flow path, and modulating acceleration length of electrons of the low-pressure gas in relation to ionization potential of the low-pressure gas in the gas flow path, to suppress ionization of the low-pressure gas in the gas flow path.

In a further aspect, the invention relates to a method of delivering a low-pressure dopant gas to a high-voltage ion source for doping of a substrate, including suppressing undesired ionization of the low-pressure dopant gas prior to entry into the high-voltage ion source, by modulating electron energy upstream of the high-voltage ion source so that electron acceleration effects are reduced to below a level supporting an electronic ionization cascade.

Other aspects, features and embodiments of the invention will be more fully apparent from the ensuing disclosure and appended claims.

### BRIEF DESCRIPTION OF THE DRAWINGS

FIG. 1 is a schematic representation of a gas delivery apparatus according to one embodiment of the present invention

FIG. 2 is a schematic representation of a gas delivery apparatus according to another embodiment of the present invention

FIG. 3 is a schematic representation of the assembly of disks, taken along line A-A of FIG. 2.

FIG. 4 is a schematic representation of a gas delivery apparatus according to a further embodiment of the invention, including a porous insulating tube defining an interior volume therein filled with ceramics spheres.

FIG. 5 is a schematic representation of a gas delivery apparatus according to yet another embodiment of the invention, including a gas delivery tube of looped conformation.

FIG. 6 is a schematic representation of a gas delivery apparatus according to a still further embodiment of the invention, which includes a looped or zig-zag tube, equipped with electrical resistance modulation between adjacent turns thereof.

FIG. 7 is a schematic illustration of a semiconductor manufacturing facility according to another aspect of the present invention.

### DETAILED DESCRIPTION OF THE INVENTION, AND PREFERRED EMBODIMENTS THEREOF

The present invention relates to delivery of low-pressure dopant gas to a high voltage ion source in the doping of materials such as semiconductor substrates.

The disclosures of U.S. Pat. No. 5,518,528 issued May 21, 1996 to Glenn M. Tom, et al. and U.S. Pat. No. 6,515,290 issued Feb. 4, 2003 Rzeszut, et al. are hereby incorporated herein by reference, in their respective entireties.

The present invention enables delivery of toxic, corrosive or flammable dopant gases from cylinders at ground potential to an ion source at high voltage. The gases must be delivered (i) safely, i.e. with no risk of catastrophic release and (ii) without risk of ionization of the gas by the electric field, which could short the high voltage.

The present invention prevents ionization discharges in low-pressure gas flowing in electric fields of the magnitude existing in external insulators in an ion implanter, viz., ˜4 kV/cm.

As used herein, the term “low-pressure” in reference to gas being delivered from a gas supply to an ion source, means gas at sub-atmospheric pressure. In specific aspects and embodiments of the invention, the low pressure may be a pressure not exceeding 700 torr, or in various other embodiments a pressure not exceeding a specific pressure value, such as 500, 400, 300, 200 or 100 torr.

The pressure dependence of gas ionization in an electric field is most easily understood in terms of the electron mean free path, Le, defined as the average distance traveled by an electron before it undergoes an ionizing collision with a gas molecule. Le is inversely proportional to pressure, and also depends on the particular gas species. At 1 torr, Le ranges from about 0.7 mm for He, to about 0.15 mm for Xe. Ionization will occur if an electron is sufficiently accelerated in the electric field to exceed the molecular ionization potential when collision occurs. For most species, the first ionization potential is between 5 and 25 eV. A discharge occurs when there is a cascade or avalanche of ionization events. In practice, due to losses in the cascade, the average electron energy at collision needs to be about twice the ionization potential for a significant discharge to occur.

In the following discussion Kr is used as an example. The ionization potential of Kr is 14 eV, and Le=0.2 mm at a pressure of 1 torr. In a field of 4 kV/cm, an electron must accelerate for about 0.1 mm to exceed twice the ionization potential—this is referred to as the “acceleration length”. At 1 torr (Le=0.2 mm), the electron will have sufficient energy when collision occurs, ionization is likely, and discharges can occur. At pressures >100 torr (Le<0.002 mm), collisions will occur before electrons have attained sufficient energy, and ionization cannot occur. At pressures <0.001 torr (Le>200 mm), electrons will gain sufficient energy but will collide with the walls of the delivery tube or vacuum chamber before a collision occurs, with the result that ionization is rare, and discharges are unlikely.

The apparatus of the present invention functions to prevent ionization in the critical pressure region around 1 torr where the acceleration length is about the same magnitude as the electron mean free path, by interrupting the acceleration of electrons in the direction of the electric field, while still allowing the flow of gas molecules.

In accordance with the invention, such interruption is achieved by the placement of surfaces in the line-of-sight path of the electrons, where the spacing between successive surfaces is in a range of from about 0.5 to about 2 times the acceleration length. Interruption of the electron acceleration prevents a cascade from developing because the electron energy is dissipated at the surfaces. The surfaces do not interrupt flow of molecules, which can occur by diffusion along paths which are not line-of-sight.

The invention in one aspect relates to a gas delivery apparatus adapted to transfer low-pressure gas from a supply thereof to an ion source characterized by an elevated voltage potential in relation to said supply. The gas delivery apparatus includes a gas flow passage, a voltage generator electrically coupled with at least a portion of the gas flow passage to impose an electric field thereon, and an obstructive structure adapted to modulate acceleration length of electrons of said low-pressure gas in relation to ionization potential of said low-pressure gas in the gas flow passage, to suppress ionization of said low-pressure gas in said gas flow passage.

In such gas delivery apparatus, the obstructive structure may be constituted by a structure selected from among non-linear conformations of the gas flow passage, and impingement structures disposed in the gas flow passage.

The obstructive structure when constituted by a non-linear conformation of the gas flow passage may have a conformation of any suitable type, such as for example a looped or zigzag conformation.

Additionally, or alternatively, the obstructive structure can include an impingement structure disposed in the gas flow passage.

The obstructive structure may be of any suitable type. Examples include: a porous material body having pore dimensions sized to block acceleration of electrons of the low-pressure gas when low-pressure gas is flowed through the gas flow passage; a baffle member positioned in the gas flow passage to prevent line-of-sight acceleration of electrons of said low-pressure gas when low-pressure gas is flowed through said gas flow passage; a bed of impingement articles, such as spherical particles of insulating material, e.g., ceramic material particles in a bed having a void volume in a range of from about 20 to about 25%, based on total volume of the bed; a porous ceramic disk having main inlet and outlet faces, which may for example be arranged in the gas flow passage with its main inlet and outlet faces oriented transverse to direction of flow of gas through the gas flow passage, so that when gas flows through the gas flow passage it flows through the porous ceramic disk from the main inlet face to the main outlet face thereof; an assembly of spaced-apart disks each having an array of apertures therein, and wherein the arrays of apertures in adjacent pairs of disks in said assembly are off-register with respect to one another; and/or any other surface element, structural member or article that in contact with the gas flowing through the gas flow passage modulates the electron energy of the gas upstream of the high-voltage ion source, so that electron acceleration effects are reduced to below a level supporting an electronic ionization cascade. The void volume in the bed is desirably as large as possible to allow free passage of gas, while still limiting electron acceleration length as required to prevent discharge.

In a specific embodiment, a porous ceramic disk can be used as an obstructive body, as mounted in an insulator body, with an inlet flange in contact with the main inlet face of the porous ceramic disk, and an outlet flange in contact with the main outlet face of the porous ceramic disk. In such arrangement, the inlet flange has an opening therein, with a gas feed tube joined in closed gas flow communication with the inlet flange opening. The outlet flange likewise has an opening therein, with a gas discharge tube joined in closed gas flow communication with the outlet flange opening. An electrical ground is connected to the inlet flange, and a voltage source is connected to the outlet flange, as components of the gas delivery apparatus.

In another specific embodiment, the gas delivery apparatus includes an assembly of spaced-apart disks, in an arrangement that includes a sequence of odd-numbered disks alternating with a sequence of even-numbered disks, wherein each of the odd-numbered disks has a same first array of apertures, and wherein each of the even-numbered disks has a same second array of apertures.

In such embodiment, the assembly of spaced-apart disks is advantageously mounted in an insulator body, with an inlet flange in spaced-apart relationship to an initial disk in the disk assembly, and an outlet flange in spaced-apart relationship to a terminal disk in the assembly. The inlet flange has an opening therein, with a gas feed tube joined in closed gas flow communication with the inlet flange opening. The outlet flange likewise has an opening therein, with a gas discharge tube joined in closed gas flow communication with the outlet flange opening. In this embodiment, an electrical ground is connected to the inlet flange, and a voltage source is connected to the outlet flange.

In another illustrative embodiment, the obstructive structure includes a bed of impingement articles that is disposed in an insulating tube enclosing a portion of the gas flow passage, with an inlet end plate enclosing a first end of the insulating tube. The inlet end plate has an opening therein. A gas feed tube is joined in closed gas flow communication with the inlet end plate opening. An outlet end plate encloses a second end of the insulating tube. The outlet end plate has an opening therein. A gas discharge tube is joined in closed gas flow communication with the outlet end plate opening, an electrical ground is connected to the inlet end plate, and a voltage source is connected to the outlet end plate.

The impingement articles in such embodiment may for example comprise ceramic spheres, or webs, sheets, screens, particulates, or other form(s) of obstructive articles.

In another specific embodiment, a non-linear conformation of the gas flow passage is provided, as a looped conformation defined by a looped tube enclosing a portion of the gas flow passage, with an inlet end plate at a first end of the looped tube. The inlet end plate has an opening therein joined in closed gas flow communication with the first end of the looped tube, with an outlet end plate at a second end of the looped tube. The outlet end plate as an opening therein joined in closed gas flow communication with the second end of the looped tube. An electrical ground is connected to the inlet end plate, and a voltage source is connected to the outlet end plate.

In a further specific embodiment, the gas delivery apparatus includes a non-linear conformation of the gas flow passage, constituted as a looped conformation defined by a looped tube enclosing a portion of the gas flow passage. An inlet end plate is provided at a first end of the looped tube. The inlet end plate has an opening therein joined in closed gas flow communication with the first end of the looped tube. And outlet end plate is provided at a second end of the looped tube, having an opening therein joined in closed gas flow communication with the second end of the looped tube. An electrical ground is connected to the inlet end plate and a voltage source is connected to the outlet end plate. A first branch line is electrically interconnected with the ground, the voltage source and a first set of loops of the looped tube, with the first branch line containing resistors on each side of the branch line interconnected with each one of said first set of loops. A second branch line is electrically interconnected with a second set of loops of the looped tube, with the second branch line containing resistors between each pair of adjacent to loops in the second set of loops.

In such embodiment, each of the resistors in the first branch line and the second branch line can have a same resistor value, or alternatively at least some of the resistors in the first branch line and the second branch line can have differing resistor values from one another.

The invention in another aspect relates to a semiconductor manufacturing facility, including a gas delivery apparatus as variously described hereinabove in respective embodiments.

In a specific semiconductor manufacturing aspect, the invention relates to a semiconductor manufacturing facility, including an ion implantation system including a low-pressure gas supply, an ion source adapted to receive low-pressure gas from the low-pressure gas supply and produce ion implant species, an implant chamber adapted to receive the ion implant species and impinge same on a semiconductor device substrate to produce an implanted substrate article, and a gas delivery apparatus adapted to transfer the low-pressure gas from the supply thereof to the ion source. The gas delivery apparatus includes a gas flow passage, a voltage generator electrically coupled with at least a portion of the gas flow passage to impose an electric field thereon, and an obstructive structure adapted to modulate acceleration length of electrons of the low-pressure gas in relation to ionization potential of the low-pressure gas in the gas flow passage, to suppress ionization of the low-pressure gas in the gas flow passage.

In a further aspect, the invention relates to a method of delivering low-pressure gas from a supply thereof to an ion source characterized by an elevated voltage potential in relation to the supply. The method includes providing a gas flow passage, imposing an electric field on at least a portion of the gas flow passage, and modulating acceleration length of electrons of the low-pressure gas in relation to ionization potential of the low-pressure gas in the gas flow passage, to suppress ionization of the low-pressure gas in the gas flow passage.

The modulating in such method can include selectively obstructing flow of the electrons in the gas flow passage, e.g., providing a non-linear gas flow passage such as a looped or zigzag conformation, and/or disposing an impingement structure in the gas flow passage.

The impingement structure can, as mentioned, include a porous material body having pore dimensions sized to block acceleration of electrons of the low-pressure gas when low-pressure gas is flowed through the gas flow passage, a baffle member positioned in the gas flow passage to prevent line-of-sight acceleration of electrons of the low-pressure gas when low-pressure gas is flowed through the gas flow passage, and/or a bed of impingement articles, such as spherical particles of insulating material, e.g., ceramic material, wherein the bed may have suitable void volume, to accommodate the flow of gas therethrough in the desired manner, such as the void volume in a range of from about 20 to about 25%, based on total volume of the bed.

Other impingement structures may be employed, such as the above-described porous ceramic disk arrangements, spaced-apart porous disk assemblies, etc., in combination with voltage source and ground components, as described, to provide a gas delivery system and method wherein undesired ionization of the gas is suppressed.

The invention therefore contemplates manufacture of semiconductor products, using a gas delivery apparatus as described herein, to deliver a gas for such manufacturing. The semiconductor product may be a microelectronic device, such as an ion-implanted microelectronic device.

In a specific aspect, the invention relates to a method of manufacturing a semiconductor product, involving ion implantation using a low-pressure gas, including ionizing the low-pressure gas to produce ion implant species, and impinging the ion implant species on a semiconductor device substrate to produce an implanted substrate article. Such method includes flowing the low-pressure gas through a gas flow path to an ion source for the ionizing, imposing an electrical field on a least a portion of the gas flow path, and modulating acceleration length of electrons of the low-pressure gas in relation to ionization potential of the low-pressure gas in the gas flow path, to suppress ionization of the low-pressure gas in the gas flow path.

Another methodological aspect of the invention relates to delivering a low-pressure dopant gas to a high-voltage ion source for doping of a substrate, including suppressing undesired ionization of the low-pressure dopant gas prior to entry into the high-voltage ion source, by modulating electron energy upstream of the high-voltage ion source so that electron acceleration effects are reduced to below a level supporting an electronic ionization cascade.

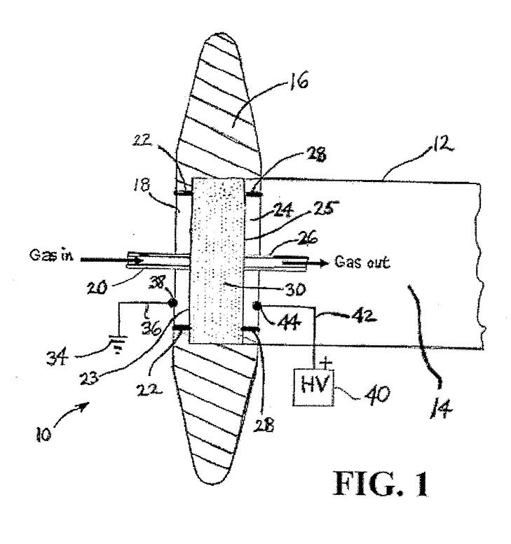

Referring now to the drawings, FIG. 1 is a schematic representation of a gas flow insulator apparatus 10 according to one embodiment of the present invention, as including a gas delivery conduit 12 defining an interior flow passage 14 therewithin. Gas flows into the apparatus 10 in a feed tube 20, in the direction indicated by the “Gas in” arrow. The feed tube 20 can be formed of any suitable metal material of construction, and is mounted in the flange 18 as shown, the flange also being formed of any suitable metal material of construction. The flange 18 in turn is mounted in the insulator body 16, and sealed by a circumferential seal 22, such as an O-ring, gasket, form-in-place sealant, or other seal element.

The feed tube 20 terminates at an upstream face 23 of a porous ceramic disk 30. At its downstream face 25, the porous ceramic disk 30 abuts flange 24 having gas discharge tube 26 mounted therein. By such arrangement, gas introduced by a gas feed tube 20 flows through the porous ceramic disk 30 and into gas discharge tube 26 for discharge therefrom, in the direction indicated by the “Gas out” arrow, to the interior flow passage 14 of the gas delivery conduit 12.

The downstream flange 24, like the upstream flange 18, is circumferentially sealed by a seal 28, such as an O-ring, gasket, form-in-place sealant, or other seal element. The tubes 20 and 26 are respectively secured to the inlet and outlet flanges 18 and 24 by welding, brazing, compression bonding, fusion bonding, adhesive bonding, or other suitable manner of securement. The inlet flange 18 is maintained at ground potential, being connected at bond 38 to ground wire 36 joined in turn to ground 34. The outlet flange 24 is maintained at high voltage, being connected at bond to 44 to wire 42 joined in turn to high voltage source 40.

The insulator 16 is formed of any suitable insulating material, such as ceramic.

The porous ceramic disk 30 is formed of a ceramic material providing a dense network of pores having an average size of less than 0.5 mm. Ceramic material of such type is more fully disclosed in U.S. Pat. No. 5,996,528, the disclosure of which hereby is incorporated by reference, in its entirety. The pores of the ceramic material allow no direct line of sight for electrons in the direction of the electric field, but gas molecules can readily diffuse through the network of pores. In one embodiment, the porous ceramic material is porous alumina, having a pore size of 0.2 to 1.0 mm and a pore density of 10 to 80 pores per inch, as commercially available from Vesuvius Hi-Tech Ceramics Inc., Alfred, N.Y.

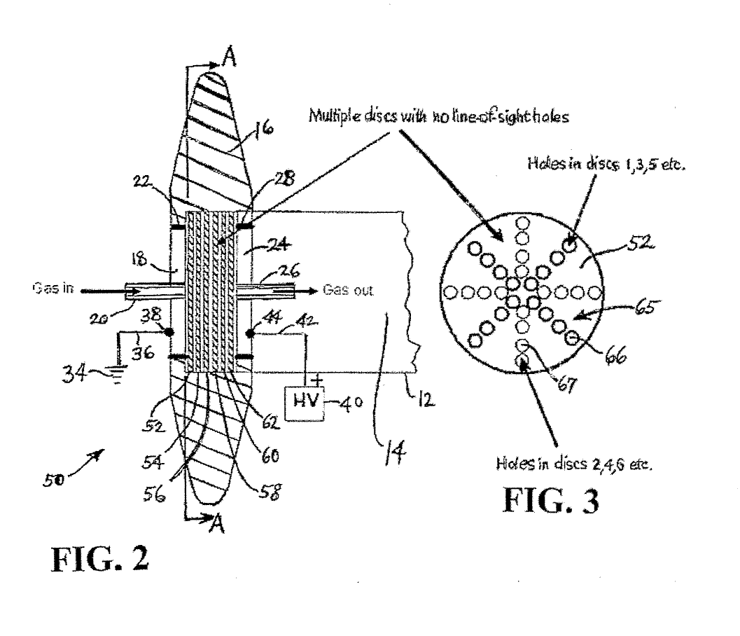

FIG. 2 is a schematic representation of a gas delivery apparatus 50 according to another embodiment of the present invention, in which corresponding elements are correspondingly numbered with respect to the same elements in FIG. 1. The apparatus of FIG. 2 differs from that of FIG. 1 by the inclusion of a series of longitudinally (in the direction of the gas flow) spaced-apart porous ceramic disks 52, 54, 56, 58, 60 and 62 coaxially arranged with respect to one another to form an assembly of successive porous disks. In such assembly, each of the constituent disks has holes therethrough, in an array, wherein the array of holes in a given disk is out of register with the array of holes in the next succeeding disk in the assembly.

This arrangement is more clearly shown in FIG. 3, which is a schematic representation of the assembly of disks, taken along line A-A of FIG. 2, showing the first disk 52 as having an array 65 of the holes 66 that all are off-register with respect to the holes 67 in the next succeeding disk 54, and wherein such off-register variation is continued throughout the stack of disks in the assembly. In this arrangement, the pattern of holes 66 in the first disk 52 is the same as the pattern of holes in the succeeding disks 56 and 60, and the pattern of holes 67 in the second disk 54 is the same as the pattern of holes in the succeeding disks 58 and 62, so that each adjacent pair of disks in the arrangement has a pattern of holes that is out of register with respect to the pattern of holes in the other one of such pair of disks.

The disks in the arrangement of FIGS. 2 and 3 may be formed of any suitable material of construction, e.g., any suitable insulating or conductive material, such as ceramic, plastic, stainless steel, etc. in a specific embodiment, the thickness of each of the disks in the arrangement is less than about 0.5 mm, and the spacing between adjacent disks is less about 0.5 mm. The disks may have any pattern of holes or apertures, and preferably such holes are formed and arranged to maximize the conductance of the gas through the disk assembly, so that there is no line-of-sight alignment of the holes in adjacent disks of the assembly.

Although the embodiments of FIG. 1 and FIG. 2 illustrate the deployment of a single gas flow insulator structure in the tube 14, it will be appreciated that multiple gas flow insulator structures can be arranged in series along the gas flow path, to isolate the full ion source voltage, within the broad practice of the present invention.

In a further embodiment, the gas flow insulator structure is surrounded by a vented enclosure (not shown in the drawings), to provide an additional measure of safety in respect of leakage from seals or breakage of ceramic pairs. In an arrangement of serial gas flow insulator structures, each gas flow insulator may be disposed in a separate vented enclosure, or the entire series of gas flow insulator structures may be disposed in a unitary vented enclosure or housing.

The foregoing embodiments of the invention prevent ionization by flowing dopant gas through porous material with pores that are sized to block the acceleration of electrons, or by inserting baffles in the flow path of dopant gas whereby a line-of-sight acceleration is prevented.

In another aspect of the present invention, ionization of the dopant gas is prevented by structural arrangements in which the acceleration of electrons, in the direction of the electric field formed in the high-voltage gap, is blocked by blocking structures of differing types than those shown in the embodiments of FIGS. 1-3 hereof. As in earlier embodiments, ionization is prevented by blocking the electrons before they attain sufficient energy to cause ionization of the gas molecules.

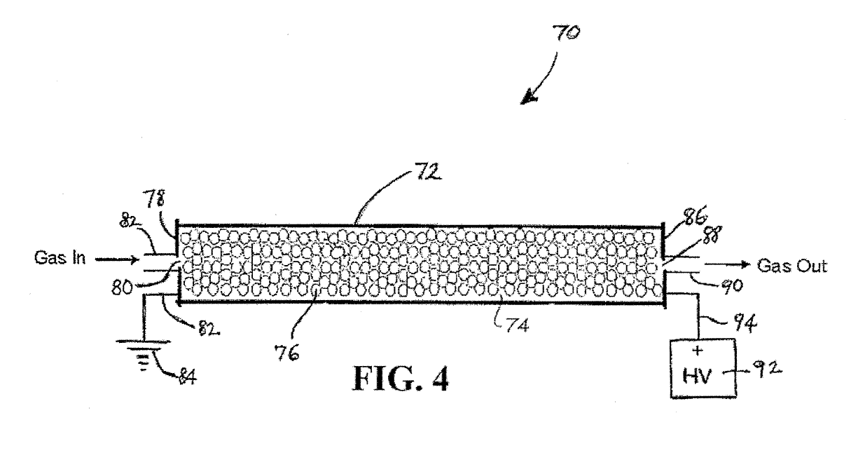

FIG. 4 is a schematic representation of a gas delivery apparatus 70 including an insulating tube 72 defining an interior volume 74 therein filled with ceramics spheres 76. The insulating tube 72 is closed at an upstream end thereof by an end plate 78 having a central opening 80 therein, to which is joined a gas feed tube 82. Gas flows into the gas feed tube in the direction indicated by the “Gas In” arrow. The end plate 78 is coupled to ground wire 82 joined in turn to ground 84. The porous insulating tube 72 is closed at a downstream end thereof by end plate 86 having a central opening 88 therein, to which is joined a gas discharge tube 90. Gas flows out a the gas discharge tube 90 in the direction indicated by the “Gas Out” arrow. The end plate 86 is coupled to a high voltage source 92 by connecting wire 94. The high voltage source can be of any suitable type, such as the high voltage DC sources commercially available from Spellman (Hauppauge, N.Y.) or Glassman High Voltage (High Bridge, N.J.). The high voltage level afforded by the high voltage source can be of any suitable character for the specific high-voltage ion source. In one embodiment, the high-voltage source provides a voltage level and arrange up from 5 to 200 kilovolts (kV).

The ceramic spheres 76 may alternatively be constructed of a non-ceramic insulating material, other any suitable type. The spheres 76 are provided in a close-packed bed having approximately 20-25% to open (interstitial) space, to allow efficient flow of the dopant gas through the bed, but these spheres are sized so that the maximum electron path lengths are a fraction of the sphere diameter, thereby preventing ionization of the gas. The overall length of the tube 72 can therefore be substantially less then if the bed of insulating spheres were absent from the interior volume 74 of the tube. The dimensions of the tube may be of any suitable values, consistent with the specific gas delivery system in which the tube is employed. In one embodiment, wherein the gas delivery pressure is in a range of from 5 to 700 torr, the tube has an inner diameter in a range of from about 0.125 inch to about 1.0 inch, and a length of from about 3 inches to about 48 inches, with end plates, porous disks and baffle disks, each having diameters in a range of from 1 inch to 8 inches, and with the ceramic spheres, having diameters to a range of from 0.5 to 3 mm. The ceramic spheres may be formed of any suitable material of construction, including, without limitation, sapphire, alumina, and quartz. In other embodiments, non-conducting polymeric spheres or beads may be employed, e.g., formed of polymeric material such as those available under the trademarks VESPEL, DELRIN and TORLON, such polymeric materials also being suitable for construction of plates and baffles for use in the delivery system of the invention.

As an alternative to the use of spheres of insulating material, other discontinuous bodies may be employed, such as fibers, threads, strands, pellets, porous webs or other forms of porous ceramic, fiberglass, polymeric or other insulating material. In general, any material can be used for the packing articles in the tube, provided the following criteria are satisfied: (i) gas flow through the tube is enabled with reasonable conductance, (ii) electronic acceleration along the length of the tube is effectively blocked, and (iii) the material is a sufficiently effective electrical insulator.

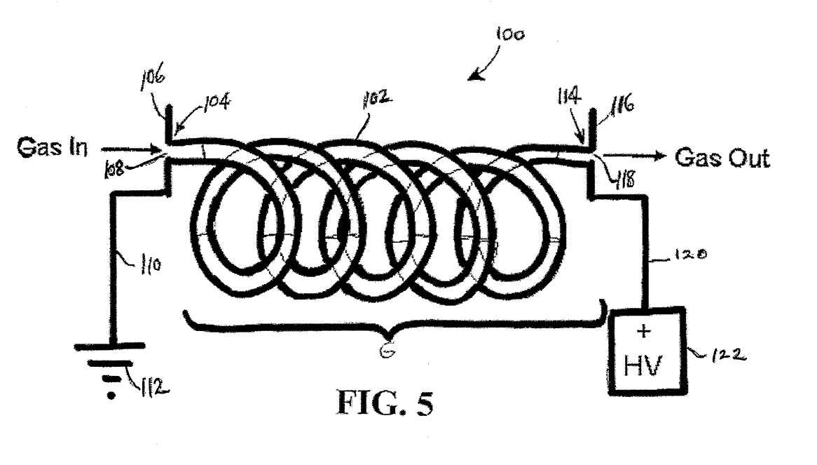

FIG. 5 is a schematic representation of a gas delivery apparatus 100 according to another embodiment of the invention. In this apparatus, an insulating tube 102 is looped across a voltage gap G, between respective inlet and outlet ends of such tube. The inlet end 104 of the looped tube 102 is joined to inlet plate 106 having a central opening 108 therein for ingress of gas in the direction indicated by the “Gas In” arrow. The inlet plate 106 is connected by a ground wire 110 to ground 112. At its opposite end, the looped tube 102 as an outlet in the 114 that is joined to outlet plate 116 adding a central opening 118 therein for outflow of gas in the direction indicated by the “Gas Out” arrow. The outlet plate 116 is joined by connecting wire 122 to high-voltage source 122, to complete the arrangement including voltage gap G.

By the arrangement shown in FIG. 5, the insulating tube 102 is looped across the voltage gap G, thereby increasing the length of the tube while maintaining a more compact configuration. At same time, the direction of the electric field is not aligned with the length of the tube, so that accelerated electrons will strike the interior surfaces of the tube, thereby preventing ionization of the gas.

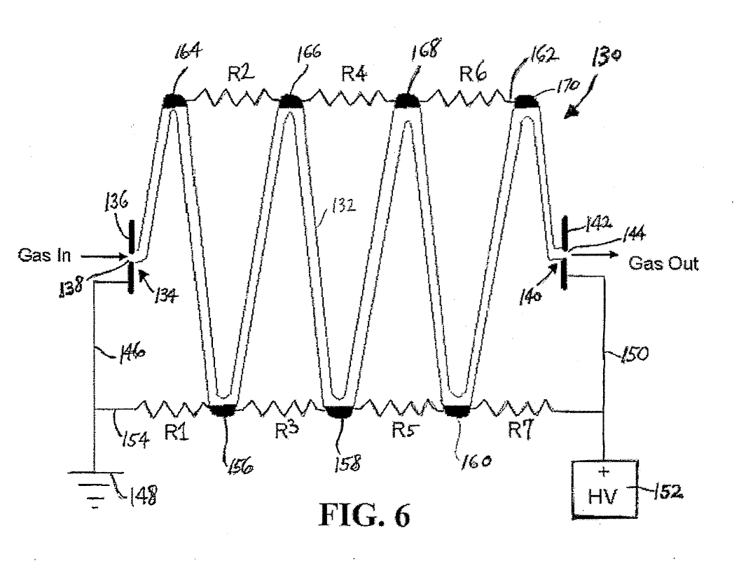

FIG. 6 is a schematic representation of a gas delivery apparatus 130 according to another embodiment of the invention, which includes a looped or zig-zag insulating tube 132 extending between the first end 134 joined in closed flow gas communication with an inlet plate 136 having a central opening 138 therein communicating with the interior passage of the tube 132. The insulating tube 132 may be sealed to the inlet plate 136 in any suitable manner, as for example by O-ring, gasket, adhesive bonding, form-in-place sealant, or other seal elements or materials. By this arrangement, gas is introduced into the tube 132 through central opening 138 in inlet plate 136, in the direction indicated by the illustrated “Gas In” arrow.

In similar manner, the second end 140 of the insulating tube 132 is joined in closed flow gas communication with an outlet plate 142 adding a central opening 144 therein communicating with the interior passage of the tube 132. The tube 132 may be sealed to the outlet plate 142 in any suitable manner, similar to that of inlet plate 136, as described.

In the FIG. 6 embodiment, the voltage drop across respective sections of the tube 132 is fixed by high voltage resistors R1, R2, R3, R4, R5, R6 and R7, arranged as shown in series-connected chains. The inlet plate 136 is connected by ground wire 146 to ground 148, and the outlet plate 142 is connected by line 150 to high-voltage source 152.

A branch line 154 interconnects the ground line 146 and the high-voltage line 150 with loops 156, 158 and 160 of tube 132. The branch line 154 contains resistor R1 in the section thereof between the ground line 146 and loop 156 of the tube 132, resistor R3 in the section of the branch line between loop 156 and loop 158 of the tube 132, resistor R5 in the section of the branch line between loop 158 and loop 160 of the tube 132, and resistor R7 in the section of the branch line between loop 160 and high-voltage line 150.

A second branch line 162 interconnects the loops 164, 166, 168 and 170 of tube 132. The branch line 162 contains resistor R2 in the section of the branch line between loop 164 and loop 166, R4 in the section of the branch line between loop 166 and loop 168, and resistor R6 in the section of the branch line between loop 168 and loop 170.

By the arrangement shown in FIG. 6, the value of the resistors may be selected to provide an appropriate gradient for preventing ionization of the dopant gas. The value of the resistors may all be the same, or each may be independently varied, as necessary or desirable to control the voltage gradient in different sections of the tube 132. It will be understood that the arrangement of resistors may be widely varied in specific embodiments, in which resistors are employed to control the distribution of the total voltage drop across various portions of the looped, coiled or zig-zagged insulating tube.

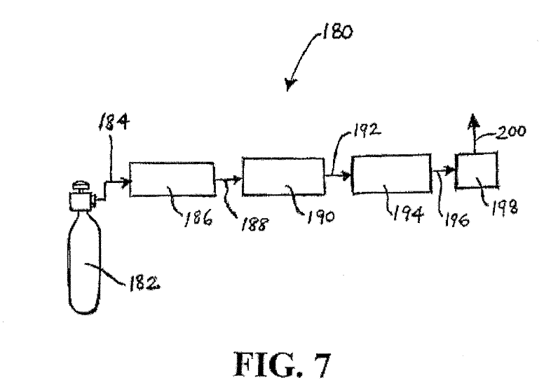

FIG. 7 is a schematic illustration of a semiconductor manufacturing facility 180 including a low-pressure dopant gas supply 182, which may for example be constituted by an adsorbent-based fluid storage and dispensing apparatus of the type disclosed in aforementioned U.S. Pat. No. 5,518,528, arranged for supplying dopant gas at sub-atmospheric pressure, e.g., a pressure below 600 torr, such as a pressure in a range of from about 10 to about 500 torr. The dopant gas, e.g., arsine, phosphine, boron trichloride, boron trifluoride, etc.

The dopant gas is flowed in feed line 184 to gas delivery unit 186, which is constructed and arranged in accordance with the present invention, to suppress ionization of the dopant gas upstream of the high-voltage inlet 188 of ion source 190, in which the dopant gas is subjected to ionization to form dopant ions of the desired character.

The resulting dopant ions are transmitted in passage 192 from the ion source 190 to the implant chamber 194, in which a wafer (not shown) is disposed in ion impingement position in relation to the ion stream of the dopant.

The byproduct effluent from the implant chamber is flowed in effluent treatment line 196 to effluent treatment unit 198, in which the effluent may be subjected to treatment and/or reclamation processing, to produce a final effluent that is discharged from the effluent treatment unit 198.

It will therefore be apparent that the form and arrangement of the invention may be widely varied, in the provision of a gas delivery apparatus in which undesired ionization of gas at low pressure is suppressed prior to entry of the gas into a high-voltage ion source, by modulating electron energy upstream of the high-voltage ion source so that electron acceleration effects are reduced to below a level supporting an electronic ionization cascade.

While the invention has been described herein in reference to specific aspects, features and illustrative embodiments of the invention, it will be appreciated that the utility of the invention is not thus limited, but rather extends to and encompasses numerous other variations, modifications and alternative embodiments, as will suggest themselves to those of ordinary skill in the field of the present invention, based on the disclosure herein. Correspondingly, the invention as hereinafter claimed is intended to be broadly construed and interpreted, as including all such variations, modifications and alternative embodiments, within its spirit and scope.

1. A gas delivery apparatus adapted to transfer low-pressure gas from a supply thereof to an ion source characterized by an elevated voltage potential in relation to said supply, said gas delivery apparatus comprising a gas flow passage, a voltage generator electrically coupled with at least a portion of the gas flow passage to impose an electric field thereon, and an obstructive structure adapted to modulate acceleration length of electrons of said low-pressure gas in relation to ionization potential of said low-pressure gas in the gas flow passage, to suppress ionization of said low-pressure gas in said gas flow passage.

2. (canceled)

3. The gas delivery apparatus of claim 1, wherein the obstructive structure comprises a non-linear conformation of said gas flow passage.

4. The gas delivery apparatus of claim 3, wherein the non-linear conformation of said gas flow passage is a looped or zigzag conformation.

5. The gas delivery apparatus of claim 1, wherein the obstructive structure comprises an impingement structure disposed in the gas flow passage.

6. The gas delivery apparatus of claim 1, wherein the obstructive structure comprises an impingement structure disposed in the gas flow passage, selected from the group consisting of:
a porous material body having pore dimensions sized to block acceleration of electrons of said low-pressure gas when low-pressure gas is flowed through said gas flow passage;
a baffle member positioned in the gas flow passage to prevent line-of-sight acceleration of electrons of said low-pressure gas when low-pressure gas is flowed through said gas flow passage;
a bed of impingement articles;
spherical particles of insulating material;
a porous ceramic disk having main inlet and outlet faces, said porous ceramic disk arranged in the gas flow passage with its main inlet and outlet faces oriented transverse to direction of flow of gas through said gas flow passage, so that when gas flows through said gas flow passage it flows through the porous ceramic disk from the main inlet face to the main outlet face thereof;
a porous ceramic disk mounted in an insulator body, with an inlet flange in contact with the main inlet face of the porous ceramic disk, and an outlet flange in contact with the main outlet face of the porous ceramic disk, said inlet flange having an opening therein, with a gas feed tube joined in closed gas flow communication with said inlet flange opening, said outlet flange having an opening therein, with a gas discharge tube joined in closed gas flow communication with said outlet flange opening, an electrical ground connected to said inlet flange, and a voltage source connected to said outlet flange; and
an assembly of spaced-apart disks each having an array of apertures therein, and wherein the arrays of apertures in adjacent pairs of disks in said assembly are off-register with respect to one another.

7-18. (canceled)

19. The gas delivery apparatus of claim 1, wherein the obstructive structure comprises a non-linear conformation of the gas flow passage, selected from the group consisting of:
a non-linear conformation of said gas flow passage comprising a looped conformation defined by a looped tube enclosing a portion of said gas flow passage, with an inlet end plate at a first end of the looped tube, said inlet end plate having an opening therein joined in closed gas flow communication with said first end of the looped tube, with an outlet end plate at a second end of the looped tube, said outlet end plate having an opening therein joined in closed gas flow communication with said second end of the looped tube, an electrical ground connected to said inlet end plate, and a voltage source connected to said outlet end plate; and
a non-linear conformation of said gas flow passage comprising a looped conformation defined by a looped tube enclosing a portion of said gas flow passage, with an inlet end plate at a first end of the looped tube, said inlet end plate having an opening therein joined in closed gas flow communication with said first end of the looped tube, with an outlet end plate at a second end of the looped tube, said outlet end plate having an opening therein joined in closed gas flow communication with said second end of the looped tube, an electrical around connected to said inlet end plate, a voltage source connected to said outlet end plate, a first branch line electrically interconnected with the ground, the voltage source and a first set of loops of said looped tube, with said first branch line containing resistors on each side of the branch line interconnected with each one of said first set of loops, and a second branch line electrically interconnected with a second set of loops of said looped tube, with said second branch line containing resistors between each pair of adjacent to loops in said second set of loops.

20-22. (canceled)

23. A semiconductor manufacturing facility, comprising a gas delivery apparatus as claimed in claim 1.

24. A semiconductor manufacturing facility, including an ion implantation system including a low-pressure gas supply, an ion source adapted to receive low-pressure gas from said low-pressure gas supply and produce ion implant species, an implant chamber adapted to receive said ion implant species and impinge same on a semiconductor device substrate to produce an implanted substrate article, and a gas delivery apparatus adapted to transfer said low-pressure gas from said supply thereof to said ion source, said gas delivery apparatus comprising a gas flow passage, a voltage generator electrically coupled with at least a portion of the gas flow passage to impose an electric field thereon, and an obstructive structure adapted to modulate acceleration length of electrons of said low-pressure gas in relation to ionization potential of said low-pressure gas in said gas flow passage, to suppress ionization of said low-pressure gas in said gas flow passage.

25. A gas delivery apparatus adapted to transfer low-pressure gas from a supply thereof to an ion source characterized by an elevated voltage potential in relation to said supply, said gas delivery apparatus comprising a gas flow passage, a voltage generator electrically coupled with at least a portion of the gas flow passage to impose an electric field thereon, an obstructive structure adapted to modulate acceleration length of electrons of said low-pressure gas in relation to ionization potential of said low-pressure gas in the gas flow passage, to suppress ionization of said low-pressure gas in said gas flow passage, and an array of resistors electrically coupled with the said voltage generator to control distribution of voltage drop along various portions of the gas flow passage.

26. (canceled)

27. A method of delivering low-pressure gas from a supply thereof to an ion source characterized by an elevated voltage potential in relation to said supply, said method comprising providing a gas flow passage, imposing an electric field on at least a portion of the gas flow passage, and modulating acceleration length of electrons of said low-pressure gas in relation to ionization potential of said low-pressure gas in the gas flow passage, to suppress ionization of said low-pressure gas in said gas flow passage.

28. The method of claim 27, wherein said modulating comprises selectively obstructing flow of said low-pressure gas in said gas flow passage.

29. The method of claim 28, wherein said selectively obstructing comprises providing a nonlinear gas flow passage as said gas flow passage.

30-48. (canceled)

49. A method of manufacturing a semiconductor product, comprising using a gas delivery apparatus as claimed in claim 1 to deliver a gas for said manufacturing.

50-51. (canceled)

52. A method of manufacturing a semiconductor product, comprising ion implantation using a low-pressure gas, including ionizing the low-pressure gas to produce ion implant species, and impinging the ion implant species on a semiconductor device substrate to produce an implanted substrate article, wherein said method comprises flowing the low-pressure gas through a gas flow path to an ion source for said ionizing, imposing an electrical field on a least a portion of the gas flow path, and modulating acceleration length of electrons of the low-pressure gas in relation to ionization potential of the low-pressure gas in the gas flow path, to suppress ionization of said low-pressure gas in the gas flow path.

53-55. (canceled)
